(19) United States
(12) Patent Application Publication
(10) Pub. No.: US 2008/0179684 A1
(43) Pub. Date: Jul. 31, 2008

(54) METHOD OF FABRICATING A STRAINED SILICON CHANNEL COMPLEMENTARY METAL OXIDE SEMICONDUCTOR TRANSISTOR AND STRUCTURE THEREOF

(76) Inventors: Chia-Wen Liang, Hsin-Chu City (TW); Wen-Han Hung, Kao-Hsiung City (TW); Cheng-Tung Huang, Kao-Hsiung City (TW); Kun-Hsien Lee, Tai-Nan City (TW); Shyh-Fann Ting, Kao-Hsiung Hsien (TW); Li-Shian Jeng, Tai-Tung Hsien (TW); Tzyy-Ming Cheng, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/668,443

(22) Filed: Jan. 29, 2007

(51) Int. Cl. H01L 27/00; H01L 21/8238

(52) U.S. Cl. 257/369; 438/218; 257/E27.046; 257/E21.632

(57) ABSTRACT

The present invention relates to a method of fabricating strained silicon channel complementary metal oxide semiconductor (CMOS) transistor by using an etching process and a planarization process such as a chemical mechanical polishing (CMP) process, and a structure thereof. The present invention is able to resolve the problem of overlap region between the stressed layers. The present invention is also able to improve the process yield and reduce the fabrication cost.

### BACKGROUND OF THE INVENTION

1. Field of the Invention

The present invention relates to a method of fabricating a strained silicon channel complementary metal oxide semiconductor (CMOS) transistor, and more particularly, to a method of fabricating a strained silicon channel CMOS transistor by using an etching process and a planarization process.

2. Description of the Prior Art

Please refer to FIG. 1 to FIG. 4. FIG. 1 to FIG. 4 show the strained silicon channel CMOS transistors fabricating process by using the contact etch stop layers (CESL) with a specific stress state. As shown in FIG. 1, a semiconductor substrate 100 is provided first and the semiconductor substrate 100 has a first active area 102, a second active area 104, and a shallow isolation trench (STI) 106 positioned between the first active area 102 and the second active area 104, and then an N type metal oxide semiconductor (NMOS) transistor 107 and a P type metal oxide semiconductor (PMOS) transistor 108 are formed on the first active area 102 and the second active area 104 respectively. The NMOS transistor 107 includes a source/drain region 109 and a first gate structure 112, and the PMOS transistor 108 includes a source/drain region 113 and a second gate structure 114. In addition, the first gate structure 112 further includes a first gate oxide layer 118, a first gate 120 positioned on the first gate oxide layer 118, a first liner 122, and a first spacer 124 positioned on the first liner 122, and the second gate structure 114 includes a second gate oxide layer 128, a second gate 130 positioned on the second gate oxide layer 128, a second liner 132, and a second spacer 134 positioned on the second liner 132. Furthermore, a salicide layer 135 is formed on the first gate 120, the second gate 130, the source/drain region 109, and the source/drain region 113.

Next, a buffer layer 136 is formed on the NMOS transistor 107, the PMOS transistor 108, and the semiconductor substrate 100. A tensile-stressed CESL 138 and an etching stop layer 140 are formed in sequence on the buffer layer 136, and then a first patterned photoresist layer 142 is formed on the etching stop layer 140 above the first active area 102 and a portion of the STI 106. Next, an etching process is carried out by using the first patterned photoresist layer 142 as an etching mask to remove the etching stop layer 140, the tensile-stressed CESL 138, and the buffer layer 136 on the second active area 104 and a portion of the STI 106, and then the first patterned photoresist layer 142 is removed, as shown in FIG. 2.

Next, as shown in FIG. 3, a compressive-stressed CESL 144 is formed on the remnant etching stop layer 140, the second active area 104, and a portion of the STI 106, and then a second patterned photoresist layer 146 is formed on the compressive-stressed CESL 144 above the second active area 104 and a portion of the STI 106. Afterward, the second patterned photoresist layer 146 is used as an etching mask to carry out an etching process to remove the compressive-stressed CESL 144 on the first active area 102 and the etching stop layer 140 is exposed. At last, the second patterned photoresist layer 146 is removed, as shown in FIG. 4.

However, the mentioned prior art has three disadvantages in the following:

1. The overlap region between the tensile-stressed CESL 138 and the compressive-stressed CESL 144 is hard to define precisely, and a partial overlap problem will happens, as shown in FIG. 4. This problem will further result in the peeling issue, and affect the stress structure function and the follow-up processes;

2. As shown in FIG. 3, when the second patterned photoresist layer 146 is used as an etching mask to carry out an etching process to remove the compressive-stressed CESL 144 on the first active area 102, the tensile-stressed CESL 138 might be damaged thereby, and the function of the tensile-stressed CESL 138 will be affected badly; and

3. In the prior art, two etching masks and two etching processes are required to fabricate the strained silicon channel CMOS transistors, and obviously, the fabrication cost is much higher.

### SUMMARY OF THE INVENTION

The present invention relates to a method of fabricating a strained silicon channel complementary metal oxide semiconductor (CMOS) transistor, and more particularly, to a method of fabricating a strained silicon channel CMOS transistor by using an etching process and a planarization process.

According to the claims, the present invention provides a method of fabricating strained silicon channel CMOS transistor device, the method comprising providing a substrate having thereon a first active area for fabricating a first transistor and a second active area for fabricating a second transistor, and an isolation structure between the first active area and the second active area, forming a first gate structure on the first active area, and a second gate structure on the second active area, forming a source/drain region of the first transistor and a source/drain region of the second transistor, forming a first stressed layer on the isolation structure, the first active area, and the second active area, forming a stop layer on the first stressed layer, forming a first mask layer on the stop layer above the first stressed layer on the first active area, removing the stop layer and the first stressed layer on the second active area, removing the first mask layer, forming a second stressed layer on the stop layer above the first active area, a portion of the isolation structure, and the second active area, forming a first dielectric layer on the second stressed layer, and performing a planarization process to polish the first dielectric layer and a portion of the second stressed layer on the stop layer until the stop layer is exposed.

According to the claims, the present invention provides another method of fabricating strained silicon channel CMOS transistor device, the method comprising providing a substrate having thereon a first active area for fabricating a first transistor and a second active area for fabricating a second transistor, and an isolation structure between the first active area and the second active area, forming a first gate structure on the first active area, and a second gate structure on the second active area, forming a source/drain region of the first transistor and a source/drain region of the second transistor, forming a first stressed layer on the isolation structure, the first active area, and the second active area, forming a first mask layer on the first stressed layer above the first active area, removing the first stressed layer on the second active area, removing the first mask layer, forming a second stressed layer on the stop layer above the first active area, a portion of the isolation structure, and the second active area, forming a first dielectric layer on the second stressed layer; and performing a planarization process to polish the first dielectric layer and a portion of the second stressed layer on the first stressed layer until the first stressed layer is exposed.

According to the claims, the present invention further provides another method of fabricating strained silicon channel CMOS transistor device, the method comprising providing a substrate having thereon a first active area for fabricating a first transistor and a second active area for fabricating a second transistor, and an isolation structure between the first active area and the second active area, forming a first gate structure on the first active area, and a second gate structure on the second active area, forming a source/drain region of the first transistor and a source/drain region of the second transistor, forming a first stressed layer on the isolation structure, the first active area, and the second active area, forming a first mask layer on the first stressed layer above the first active area, removing the first stressed layer on the second active area, removing the first mask layer, forming a second stressed layer on the stop layer above the first active area, a portion of the isolation structure, and the second active area, forming a first dielectric layer on the second stressed layer, forming a second dielectric layer on the first dielectric layer; and performing a planarization process to polish the second dielectric layer.

According to the claims, the present invention provides a structure of strained silicon channel CMOS transistor device comprising a substrate, the substrate having thereon at least a first active area, at least a second active area, and an isolation structure between the first active area and the second active area, a first transistor, positioned on the first active area, a second transistor, positioned on the second active area, a first stressed layer, positioned on a portion of the isolation structure and the first transistor, a stop layer, positioned on the first stressed layer, a second stressed layer, positioned on a portion of the stop layer above the first transistor, and covering the isolation structure and the second transistor, and a first dielectric layer, positioned on a portion of the second stressed layer, wherein a top surface of the stop layer on the first transistor and a top surface of the first dielectric layer are in the same plane.

According to the claims, the present invention provides another structure of strained silicon channel CMOS transistor device comprising a substrate, the substrate having thereon at least a first active area, at least a second active area, and an isolation structure between the first active area and the second active area, a first transistor, positioned on the first active area, a second transistor, positioned on the second active area, a first stressed layer, positioned on a portion of the isolation structure and the first transistor, a stop layer, positioned on the first stressed layer, a second stressed layer, positioned on a portion of the first stressed layer above the first transistor, a portion of the isolation structure, and the second transistor, and a first dielectric layer, positioned on a portion of the second stressed layer, wherein a top surface of the first stressed layer on the first transistor and a top surface of the first dielectric layer are in the same plane.

According to the claims, the present invention further provides another structure of strained silicon channel CMOS transistor device comprising a substrate, the substrate having thereon at least a first active area, at least a second active area, and an isolation structure between the first active area and the second active area, a first transistor, positioned on the first active area, a second transistor, positioned on the second active area, a first stressed layer, positioned on a portion of the isolation structure and the first transistor, a second stressed layer, positioned on a portion of the first stressed layer above the first transistor, a portion of the isolation structure, and the second transistor, and a first dielectric layer, positioned on a portion of the second stressed layer, wherein a top surface of the first stressed layer on the first transistor and a top surface of the first dielectric layer are in the same plane.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 show the strained silicon channel CMOS transistors fabricating process by using the contact etch stop layers (CESL) with a specific stress state.

FIG. 5 to FIG. 8 show schematic, cross-sectional diagrams illustrating a fabricating method of a strained silicon channel CMOS transistor in accordance with the first preferred embodiment of the present invention.

FIG. 9 to FIG. 12 show schematic, cross-sectional diagrams illustrating a fabricating method of a strained silicon channel CMOS transistor in accordance with the second preferred embodiment of the present invention.

FIG. 13 to FIG. 16 show schematic, cross-sectional diagrams illustrating a fabricating method of a strained silicon channel CMOS transistor in accordance with the third preferred embodiment of the present invention.

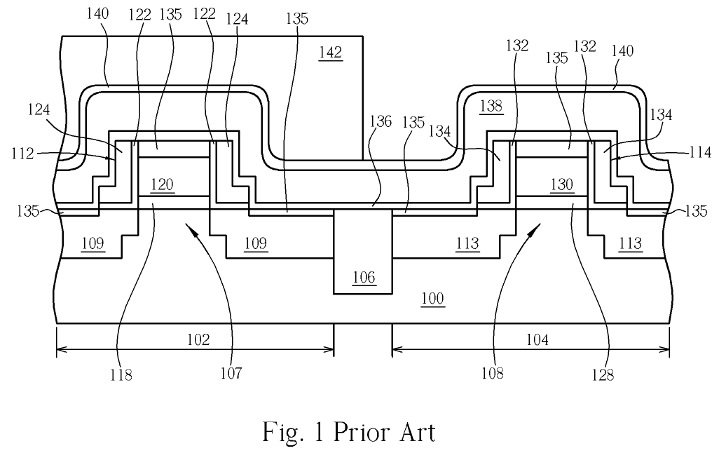

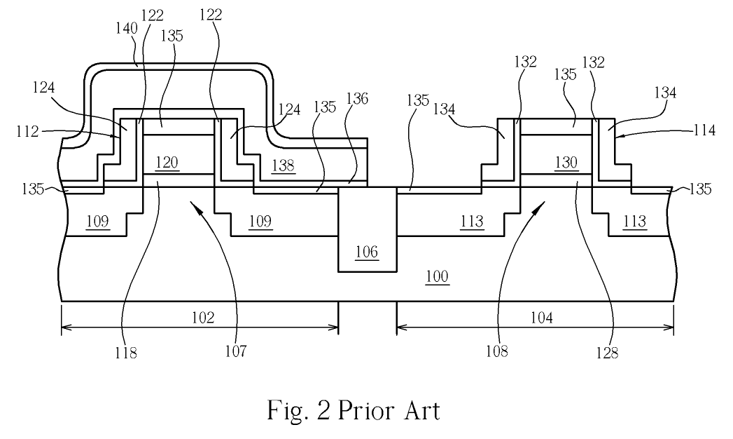

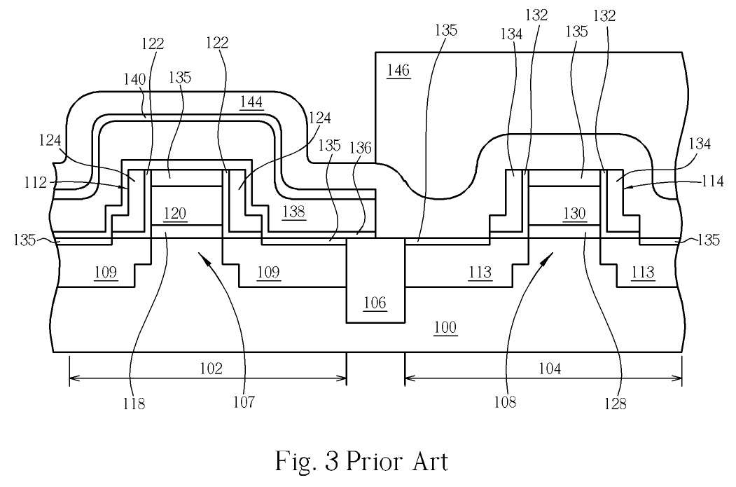

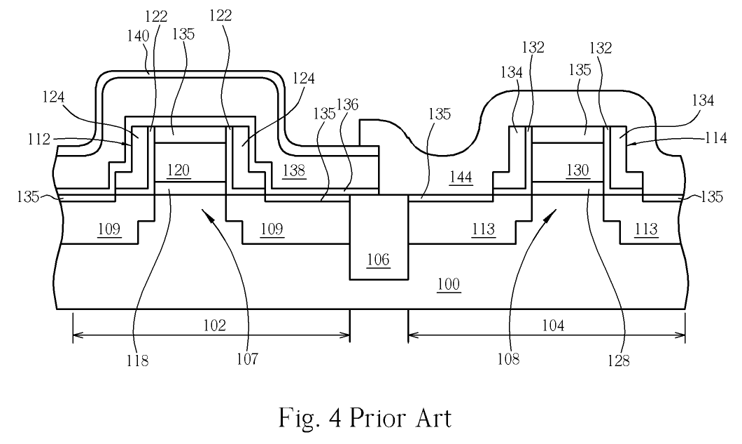

### DETAILED DESCRIPTION

The present invention relates to a method of fabricating a strained silicon channel CMOS transistor by using the contact etch stop layers (CESL) with a specific stress state, and the technology of combining a compressive-stressed CESL and a tensile-stressed CESL into the CMOS device is called the selective strain scheme (SSS).

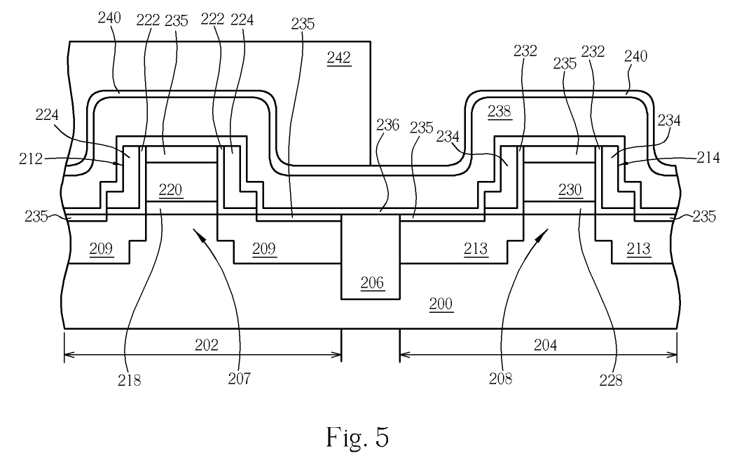

Please refer to FIG. 5 to FIG. 8. FIG. 5 to FIG. 8 show schematic, cross-sectional diagrams illustrating a fabricating method of a strained silicon channel complementary metal oxide semiconductor (CMOS) transistor in accordance with the first preferred embodiment of the present invention. The present invention first provides a substrate 200, and the substrate 200 has a first active area 202, a second active area 204, and an isolation structure 206 such as a shallow trench isolation (STI), or a local oxidation of silicon isolation layers (LOCOS), etc., positioned between the first active area 202 and the second active area 204, wherein the substrate 200 is a semiconductor substrate, but is not limited to a silicon wafer or a SOI.

Next, as shown in FIG. 5, a first transistor 207 and a second transistor 208 are formed on the first active area 202 and the second active area 204 respectively. The first transistor 207 includes a source/drain region 209 and a first gate structure 212, and the second transistor 208 includes a source/drain region 213 and a second gate structure 214. In addition, the first gate structure 212 further includes a first gate dielectric layer 218, a first gate 220 positioned on the first gate dielectric layer 218, a first liner 222, and a first spacer 224 positioned on the first liner 222, and the second gate structure 214 includes a second gate dielectric layer 228, a second gate 230 positioned on the second gate dielectric layer 228, a second liner 232, and a second spacer 234 positioned on the second liner 232. Furthermore, a salicide layer 235 is formed on the first gate 220, the second gate 230, the source/drain region 209, and the source/drain region 213. The first gate dielectric layer 218 and the second gate dielectric layer 228 can be composed of silicon dioxide (SiO2), and the first gate 220 and the second gate 230 can be composed of doped polysilicon. The first liner 222 and the second liner 232 can be an offset spacer composed of silicon oxide, and the shapes of the first liner 222 and the second liner 232 are often like an “L”. The first spacer 224 and the second spacer 234 can include compounds of silicon with nitride or silicon with oxide. The L-shaped spacer can strengthen effects of the stressed layer. In addition, a salicide layer 235 can be formed on the first gate 220, the second gate 230, the source/drain region 209, and the source/drain region 213.

Next, a buffer layer 236 is formed on the first transistor 207, the second transistor 208, and the semiconductor substrate 200. A first stressed layer 238 and a stop layer 240 are formed in sequence on the buffer layer 236, and then a first mask layer 242 is formed on the stop layer 240 above the first active area 202 and a portion of the isolation structure 206. The first stressed layer 238 can be a CESL with a specific stress state. In addition, the buffer layer 236 and the stop layer 240 can include silicon oxide, and the thickness of the buffer layer 236 can be 0 to 100 angstroms, and the thickness of the stop layer 240 can be 100 to 1000 angstroms. Furthermore, the first mask layer 242 can be a patterned photoresist layer.

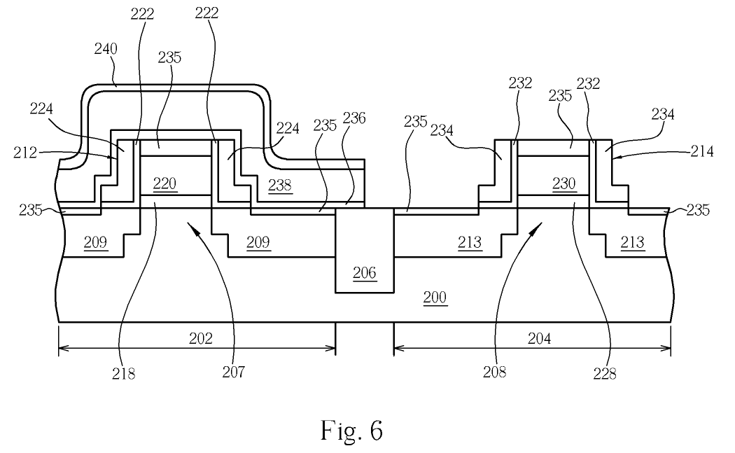

Next, an etching process such as an anisotropic dry etching process is carried out by using the first mask layer 242 as an etching mask to remove the stop layer 240, the first stressed layer 238, and the buffer layer 236 on the second active area 204 and a portion of the isolation structure 206, and then the first mask layer 242 is removed, as shown in FIG. 6.

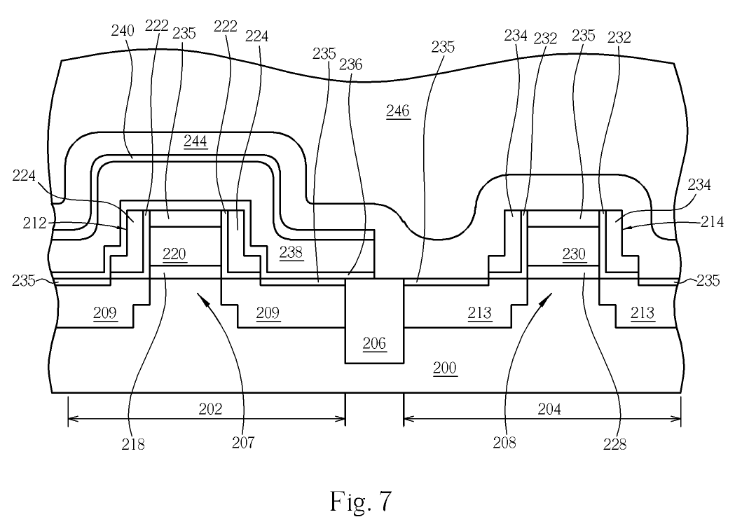

Next, as shown in FIG. 7, a second stressed layer 244 is formed on the remnant stop layer 240, the second active area 204, and a portion of the isolation structure 206, and then a first dielectric layer 246 such as a SiO2 layer is formed on the second stressed layer 244. The second stressed layer 244 can be a CESL with a specific stress state. For example, when the first transistor 207 is P type metal oxide semiconductor (PMOS) transistor, and the second transistor 208 is an N type metal oxide semiconductor (NMOS) transistor, then the first stressed layer 238 is a compressive-stressed CESL, and the second stressed layer 244 is a tensile-stressed CESL. On the contrary, when the first transistor 207 is a NMOS transistor, and the second transistor 208 is a PMOS transistor, then the first stressed layer 238 is a tensile-stressed CESL, and the second stressed layer 244 is a compressive-stressed CESL. In addition, the thickness of the first dielectric layer 246 can be 100 to 1000 angstroms, and the thickness of the first stressed layer 238 and the second stressed layer 244 can be 500 to 1500 angstroms.

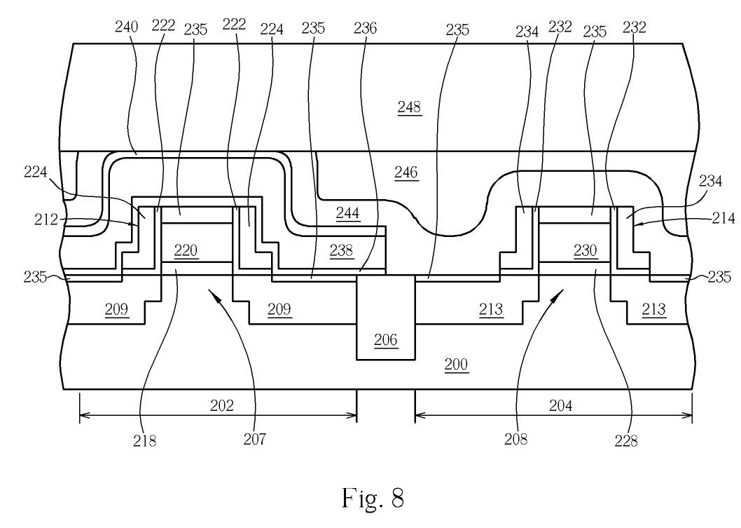

Next, as shown in FIG. 8, a planarization process such as a chemical mechanical polishing (CMP) process or a time mode CMP process is carried out to polish the first dielectric layer 246 and a portion of the second stressed layer 244 on the stop layer 240 until the stop layer 240 is exposed. Then, a second dielectric layer 248 such as a SiO₂ layer with thickness of about 2000 to 4000 angstroms can be optionally formed on the first dielectric layer 246, and on the stop layer 240 and the second stressed layer 244 above and the first active area 202. Another planarization process such as a CMP process can be optionally carried out to polish the second dielectric layer 248 in order to complete an inter layer dielectric (ILD) layer process. At last, a contact plug process is carried out to form a plurality of contact plugs (not shown) in order to properly electrically connect the first gate 220, the second gate 230, the source/drain region 209, the source/drain region 213, and the follow-up metal interconnection.

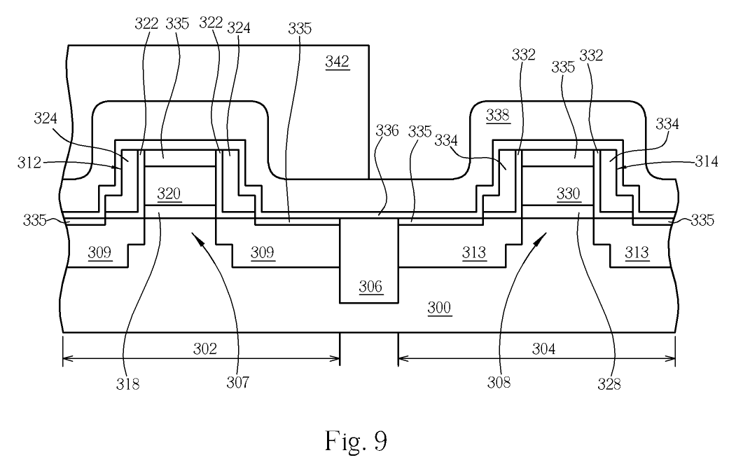

Please refer to FIG. 9 to FIG. 12. FIG. 9 to FIG. 12 show schematic, cross-sectional diagrams illustrating a fabricating method of a strained silicon channel CMOS transistor in accordance with the second preferred embodiment of the present invention. The present invention first provides a substrate 300, and just as with the first preferred embodiment, the substrate 300 has a first active area 302, a second active area 304, and an isolation structure 306 positioned between the first active area 302 and the second active area 304.

Next, as shown in FIG. 9, a first transistor 307 and a second transistor 308 are formed on the first active area 302 and the second active area 304 respectively. The first transistor 307 includes a source/drain region 309 and a first gate structure 312, and the second transistor 308 includes a source/drain region 313 and a second gate structure 314. In addition, the first gate structure 312 further includes a first gate dielectric layer 318, a first gate 320 positioned on the first gate dielectric layer 318, a first liner 322, and a first spacer 324 positioned on the first liner 322, and the second gate structure 314 includes a second gate dielectric layer 328, a second gate 330 positioned on the second gate dielectric layer 328, a second liner 332, and a second spacer 334 positioned on the second liner 332. Furthermore, a salicide layer 335 is formed on the first gate 320, the second gate 330, the source/drain region 309, and the source/drain region 313. The first gate dielectric layer 318 and the second gate dielectric layer 328 can be composed of SiO2, and the first gate 320 and the second gate 330 can be composed of doped polysilicon. The first liner 322 and the second liner 332 can be an offset spacer composed of silicon oxide, and the shapes of the first liner 322 and the second liner 332 are often like an “L”. The first spacer 324 and the second spacer 334 can include compounds of silicon with nitride or silicon with oxide. The L-shaped spacer can strengthen effects of the stressed layer. In addition, a salicide layer 335 can be formed on the first gate 320, the second gate 330, the source/drain region 309, and the source/drain region 313.

Next, a buffer layer 336 is formed on the first transistor 307, the second transistor 308, and the semiconductor substrate 300. A first stressed layer 338 is formed on the buffer layer 336, and then a first mask layer 342 is formed on the first stressed layer 338 above the first active area 302 and a portion of the isolation structure 306. The first stressed layer 338 can be a CESL with a specific stress state. In addition, the buffer layer 336 can include silicon oxide, and the thickness of the buffer layer 336 can be 0 to 100 angstroms. Furthermore, the first mask layer 342 can be a patterned photoresist layer.

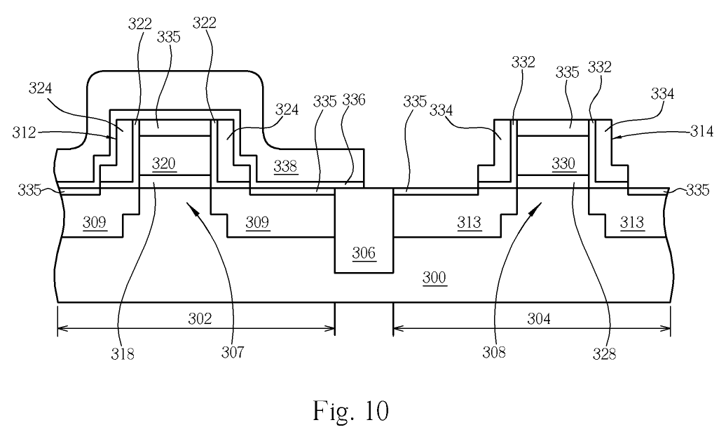

Next, an etching process such as an anisotropic dry etching process is carried out by using the first mask layer 342 as an etching mask to remove the first stressed layer 338 and the buffer layer 336 on the second active area 304 and a portion of the isolation structure 306, and then the first mask layer 342 is removed, as shown in FIG. 10.

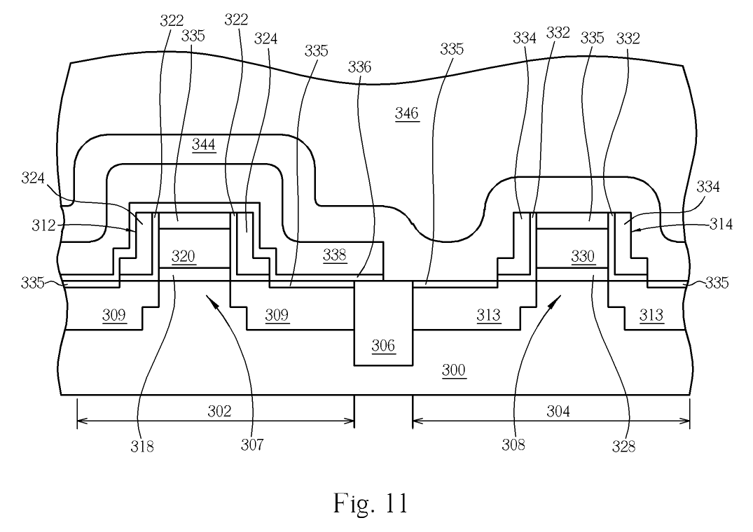

Next, as shown in FIG. 11, a second stressed layer 344 is formed on the remnant first stressed layer 338, the second active area 304, and a portion of the isolation structure 306, and then a first dielectric layer 346 such as a SiO2 layer is formed on the second stressed layer 344. The second stressed layer 344 can be a CESL with a specific stress state. For example, when the first transistor 307 is a PMOS transistor, and the second transistor 308 is a NMOS transistor, then the first stressed layer 338 is a compressive-stressed CESL, and the second stressed layer 344 is a tensile-stressed CESL. On the contrary, when the first transistor 307 is a NMOS transistor, and the second transistor 308 is a PMOS transistor, then the first stressed layer 338 is a tensile-stressed CESL, and the second stressed layer 344 is a compressive-stressed CESL. In addition, the thickness of the first dielectric layer 346 can be 100 to 1000 angstroms, and the thickness of the first stressed layer 338 and the second stressed layer 344 can be 500 to 1500 angstroms.

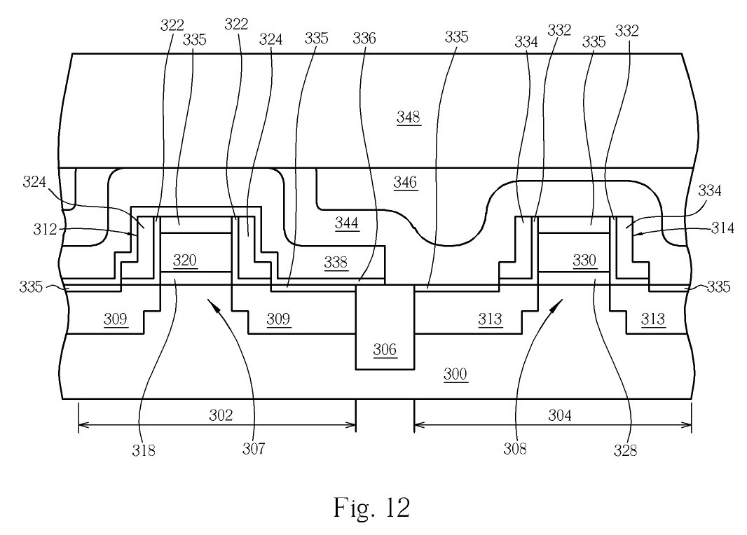

Next, as shown in FIG. 12, a planarization process such as a CMP process or a time mode CMP process is carried out to polish the first dielectric layer 346 and a portion of the second stressed layer 344 on the first stressed layer 338 until the first stressed layer 338 is exposed. Then, a second dielectric layer 348 such as a SiO₂ layer with thickness of about 2000 to 4000 angstroms can be optionally formed on the first dielectric layer 346, and on the stop layer 340 and the second stressed layer 344 above and the first active area 302. Another planarization process such as a CMP process can be optionally carried out to polish the second dielectric layer 348 in order to complete an ILD layer process. At last, a contact plug process is carried out to form a plurality of contact plugs (not shown) in order to properly electrically connect the first gate 320, the second gate 330, the source/drain region 309, the source/drain region 313, and the follow-up metal interconnect.

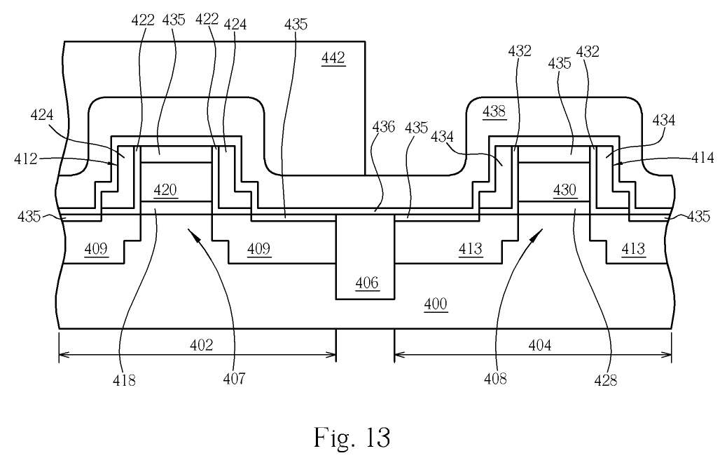

Please refer to FIG. 13 to FIG. 16. FIG. 13 to FIG. 16 show schematic, cross-sectional diagrams illustrating a fabricating method of a strained silicon channel CMOS transistor in accordance with the third preferred embodiment of the present invention. The present invention first provides a substrate 400, and just as with the first and the second preferred embodiments, the substrate 400 has a first active area 402, a second active area 404, and an isolation structure 406 positioned between the first active area 402 and the second active area 404.

Next, as shown in FIG. 13, a first transistor 407 and a second transistor 408 are formed on the first active area 402 and the second active area 404 respectively. The first transistor 407 includes a source/drain region 409 and a first gate structure 412, and the second transistor 408 includes a source/drain region 413 and a second gate structure 414. In addition, the first gate structure 412 further includes a first gate dielectric layer 418, a first gate 420 positioned on the first gate dielectric layer 418, a first liner 422, and a first spacer 424 positioned on the first liner 422, and the second gate structure 414 includes a second gate dielectric layer 428, a second gate 430 positioned on the second gate dielectric layer 428, a second liner 432, and a second spacer 434 positioned on the second liner 432. Furthermore, a salicide layer 435 is formed on the first gate 420, the second gate 430, the source/drain region 409, and the source/drain region 413. The first gate dielectric layer 418 and the second gate dielectric layer 428 can be composed of SiO2, and the first gate 420 and the second gate 430 can be composed of doped polysilicon. The first liner 422 and the second liner 432 can be an offset spacer composed of silicon oxide, and the shapes of the first liner 422 and the second liner 432 are often like an “L”. The first spacer 424 and the second spacer 434 can include compounds of silicon with nitride or silicon with oxide. The L-shaped spacer can strengthen effects of the stressed layer. In addition, a salicide layer 435 can be formed on the first gate 420, the second gate 330, the source/drain region 409, and the source/drain region 413.

Next, a buffer layer 436 is formed on the first transistor 407, the second transistor 408, and the semiconductor substrate 400. A first stressed layer 438 is formed on the buffer layer 436, and then a first mask layer 442 is formed on the first stressed layer 438 above the first active area 402 and a portion of the isolation structure 406. The first stressed layer 438 can be a CESL with a specific stress state. In addition, the buffer layer 436 can include silicon oxide, and the thickness of the buffer layer 436 can be 0 to 100 angstroms. Furthermore, the first mask layer 442 can be a patterned photoresist layer.

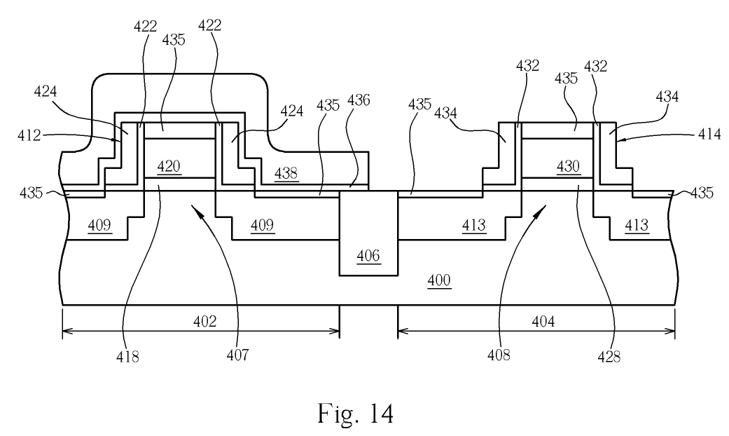

Next, an etching process such as an anisotropic dry etching process is carried out by using the first mask layer 442 as an etching mask to remove the first stressed layer 438 and the buffer layer 436 on the second active area 404 and a portion of the isolation structure 406, and then the first mask layer 442 is removed, as shown in FIG. 14.

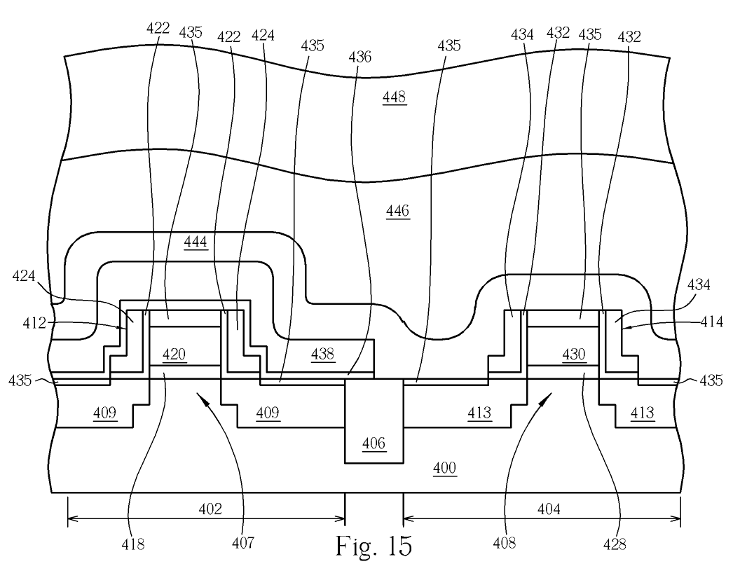

Next, as shown in FIG. 15, a second stressed layer 444 is formed on the remnant first stressed layer 438, the second active area 404, and a portion of the isolation structure 406, and then a first dielectric layer 446 and a second dielectric layer 448 are formed on the second stressed layer 444 in sequence. The second stressed layer 444 can be a CESL with a specific stress state. For example, when the first transistor 407 is a PMOS transistor, and the second transistor 408 is a NMOS transistor, then the first stressed layer 438 is a compressive-stressed CESL, and the second stressed layer 444 is a tensile-stressed CESL. On the contrary, when the first transistor 407 is a NMOS transistor, and the second transistor 408 is a PMOS transistor, then the first stressed layer 438 is a tensile-stressed CESL, and the second stressed layer 444 is a compressive-stressed CESL. In addition, the thickness of the first dielectric layer 446 can be 100 to 1000 angstroms, and the second dielectric layer 448 can be 2000 to 4000 angstroms, and the thickness of the first stressed layer 438 and the second stressed layer 444 can be 500 to 1500 angstroms.

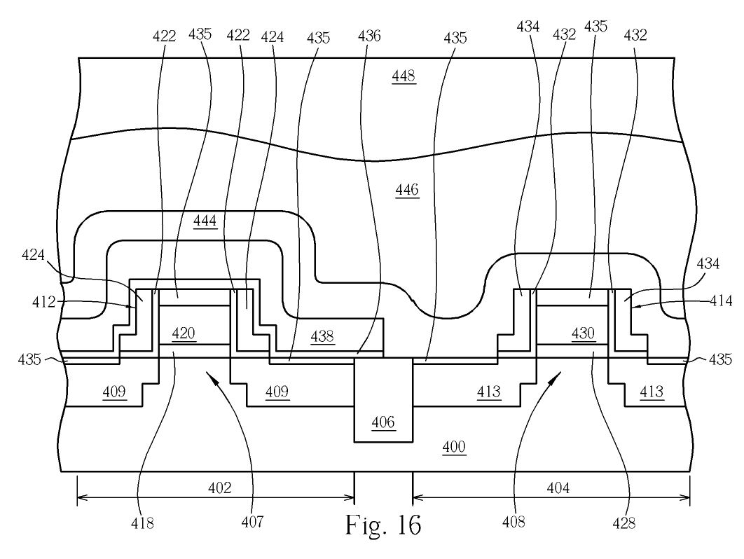

Next, as shown in FIG. 16, a planarization process such as a CMP process is carried out to polish the second dielectric layer 448 in order to complete an ILD layer process, and then a contact plug process can be optionally carried out to form a plurality of contact plugs (not shown) in order to properly electrically connect the first gate 420, the second gate 430, the source/drain region 409, the source/drain region 413, and the follow-up metal interconnect.

Since the method of the present invention uses the etching process and the planarization process such as the CMP process to fabricate the strained silicon channel CMOS transistor, the overlap problem between the first stressed layer and the second stressed layer can be resolved easily, and the present invention also can avoid damaging the second stressed layer to improve the process yield. In addition, only one etching mask and one etching process are required to fabricate the strained silicon channel CMOS transistors in the present invention, and therefore the fabrication cost can be reduced substantially.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating strained silicon channel complementary metal oxide semiconductor (CMOS) transistor device, the method comprising:
providing a substrate having thereon a first active area for fabricating a first transistor and a second active area for fabricating a second transistor, and an isolation structure between the first active area and the second active area;
forming a first gate structure on the first active area, and a second gate structure on the second active area;
forming a source/drain region of the first transistor and a source/drain region of the second transistor;
forming a first stressed layer on the isolation structure, the first active area, and the second active area;
forming a stop layer on the first stressed layer;
forming a first mask layer on the stop layer above the first stressed layer on the first active area;
removing the stop layer and the first stressed layer on the second active area;
removing the first mask layer;
forming a second stressed layer on the stop layer above the first active area, a portion of the isolation structure, and the second active area;
forming a first dielectric layer on the second stressed layer; and
performing a planarization process to polish the first dielectric layer and a portion of the second stressed layer on the stop layer until the stop layer is exposed.

2. The method of claim 1 wherein after performing the planarization process to expose the stop layer, the method further comprises:
forming a second dielectric layer on the first dielectric layer, the stop layer and the first stressed layer above the first active area; and
performing a contact plug process to form at least a contact plug.

3. The method of claim 1 wherein the first gate structure further comprises:
a first gate dielectric layer;
a first gate, positioned on the first gate dielectric layer, the first gate having a sidewall; and
a first spacer, positioned on the sidewall of the first gate.

4. The method of claim 1 wherein the second gate structure further comprises:
a second gate dielectric layer;
a second gate, positioned on the second gate dielectric layer, the second gate having a sidewall; and
a second spacer, positioned on the sidewall of the second gate.

5. The method of claim 1 wherein the first transistor comprises a P type metal oxide semiconductor (PMOS) transistor, and the second transistor comprises an N type metal oxide semiconductor (NMOS) transistor.

6. The method of claim 5 wherein the first stressed layer is a compressive-stressed contact etch stop layer (CESL), and the second stressed layer is a tensile-stressed CESL.

7. The method of claim 1 wherein the first transistor comprises a NMOS transistor, and the second transistor comprises a PMOS transistor.

8. The method of claim 7 wherein the first stressed layer is a tensile-stressed CESL, and the second stressed layer is a compressive-stressed CESL.

9. The method of claim 1 wherein the planarization process comprises a chemical mechanical polishing (CMP) process or a time mode CMP process.

10. The method of claim 1 wherein before forming the first stressed layer on the isolation structure, the first active area, and the second active area, the method further comprises:
forming a buffer layer on the isolation structure, the first active area, and the second active area.

11. A method of fabricating strained silicon channel CMOS transistor device, the method comprising:
providing a substrate having thereon a first active area for fabricating a first transistor and a second active area for fabricating a second transistor, and an isolation structure between the first active area and the second active area;
forming a first gate structure on the first active area, and a second gate structure on the second active area;
forming a source/drain region of the first transistor and a source/drain region of the second transistor;
forming a first stressed layer on the isolation structure, the first active area, and the second active area;
forming a first mask layer on the first stressed layer above the first active area;
removing the first stressed layer on the second active area;
removing the first mask layer;
forming a second stressed layer on the stop layer above the first active area, a portion of the isolation structure, and the second active area;
forming a first dielectric layer on the second stressed layer; and
performing a planarization process to polish the first dielectric layer and a portion of the second stressed layer on the first stressed layer until the first stressed layer is exposed.

12. The method of claim 11 wherein after performing the planarization process to expose the stop layer, the method further comprises:
forming a second dielectric layer on the first dielectric layer, the first stressed layer above the first active area; and
performing a contact plug process to form at least a contact plug.

13. The method of claim 11 wherein the first gate structure further comprises:
a first gate dielectric layer;
a first gate, positioned on the first gate dielectric layer, the first gate having a sidewall; and
a first spacer, positioned on the sidewall of the first gate.

14. The method of claim 111 wherein the second gate structure further comprises:
a second gate dielectric layer;
a second gate, positioned on the second gate dielectric layer, the second gate having a sidewall; and
a second spacer, positioned on the sidewall of the second gate.

15. The method of claim 11 wherein the first transistor comprises a PMOS transistor, and the second transistor comprises a NMOS transistor.

16. The method of claim 15 wherein the first stressed layer is a compressive-stressed CESL, and the second stressed layer is a tensile-stressed CESL.

17. The method of claim 11 wherein the first transistor comprises a NMOS transistor, and the second transistor comprises a PMOS transistor.

18. The method of claim 17 wherein the first stressed layer is a tensile-stressed CESL, and the second stressed layer is a compressive-stressed CESL.

19. The method of claim 11 wherein the planarization process comprises a CMP process or a time mode CMP process.

20. The method of claim 1 wherein before forming the first stressed layer on the isolation structure, the first active area, and the second active area further comprises:
forming a buffer layer on the isolation structure, the first active area, and the second active area.

21. A method of fabricating strained silicon channel CMOS transistor device, the method comprising:
providing a substrate having thereon a first active area for fabricating a first transistor and a second active area for fabricating a second transistor, and an isolation structure between the first active area and the second active area;
forming a first gate structure on the first active area, and a second gate structure on the second active area;
forming a source/drain region of the first transistor and a source/drain region of the second transistor;
forming a first stressed layer on the isolation structure, the first active area, and the second active area;
forming a first mask layer on the first stressed layer above the first active area;
removing the first stressed layer on the second active area;
removing the first mask layer;
forming a second stressed layer on the stop layer above the first active area, a portion of the isolation structure, and the second active area;
forming a first dielectric layer on the second stressed layer;
forming a second dielectric layer on the first dielectric layer; and
performing a planarization process to polish the second dielectric layer.

22. The method of claim 21 wherein after performing the planarization process to polish the second dielectric layer, the method further comprises performing a contact plug process to form at least a contact plug.

23. The method of claim 21 wherein the first gate structure further comprises:
a first gate dielectric layer;
a first gate, positioned on the first gate dielectric layer, the first gate having a sidewall; and
a first spacer, positioned on the sidewall of the first gate.

24. The method of claim 21 wherein the second gate structure further comprises:
a second gate dielectric layer;
a second gate, positioned on the second gate dielectric layer, the second gate having a sidewall; and
a second spacer, positioned on the sidewall of the second gate.

25. The method of claim 21 wherein the first transistor comprises a PMOS transistor, and the second transistor comprises a NMOS transistor.

26. The method of claim 25 wherein the first stressed layer is a compressive-stressed CESL, and the second stressed layer is a tensile-stressed CESL.

27. The method of claim 21 wherein the first transistor comprises a NMOS transistor, and the second transistor comprises a PMOS transistor.

28. The method of claim 27 wherein the first stressed layer is a tensile-stressed CESL, and the second stressed layer is a compressive-stressed CESL.

29. The method of claim 21 wherein the planarization process comprises a CMP process.

30. A structure of strained silicon channel CMOS transistor device comprising:
a substrate, the substrate having thereon at least a first active area, at least a second active area, and an isolation structure between the first active area and the second active area;
a first transistor, positioned on the first active area;
a second transistor, positioned on the second active area;
a first stressed layer, positioned on a portion of the isolation structure and the first transistor;
a stop layer, positioned on the first stressed layer;
a second stressed layer, positioned on a portion of the stop layer above the first transistor, and covering the isolation structure and the second transistor; and
a first dielectric layer, positioned on a portion of the second stressed layer, wherein a top surface of the stop layer on the first transistor and a top surface of the first dielectric layer are in the same plane.

31. The structure of claim 30 further comprising:
a second dielectric layer, positioned on the top surface of the stop layer on the first transistor and the top surface of the first dielectric layer; and
at least a contact plug.

32. The structure of claim 30 wherein the first transistor further comprises:
a first gate dielectric layer;
a first gate, positioned on the first gate dielectric layer, the first gate having a sidewall;
a first spacer, positioned on the sidewall of the first gate; and
a source/drain region.

33. The structure of claim 30 wherein the second transistor further comprises:
a second gate dielectric layer;
a second gate, positioned on the second gate dielectric layer, the second gate having a sidewall;
a second spacer, positioned on the sidewall of the second gate; and
a source/drain region.

34. The structure of claim 30 wherein the first transistor comprises a PMOS transistor, and the second transistor comprises a NMOS transistor.

35. The structure of claim 34 wherein the first stressed layer is a compressive-stressed CESL, and the second stressed layer is a tensile-stressed CESL.

36. The structure of claim 30 wherein the first transistor comprises a NMOS transistor, and the second transistor comprises a PMOS transistor.

37. The structure of claim 36 wherein the first stressed layer is a tensile-stressed CESL, and the second stressed layer is a compressive-stressed CESL.

38. The structure of claim 30 further comprising a buffer layer on a portion of the isolation structure and the first transistor, and below the first stressed layer.

39. A structure of strained silicon channel CMOS transistor device comprising:
a substrate, the substrate having thereon at least a first active area, at least a second active area, and an isolation structure between the first active area and the second active area;
a first transistor, positioned on the first active area;
a second transistor, positioned on the second active area;
a first stressed layer, positioned on a portion of the isolation structure and the first transistor;
a stop layer, positioned on the first stressed layer;
a second stressed layer, positioned on a portion of the first stressed layer above the first transistor, a portion of the isolation structure, and the second transistor; and
a first dielectric layer, positioned on a portion of the second stressed layer, wherein a top surface of the first stressed layer on the first transistor and a top surface of the first dielectric layer are in the same plane.

40. The structure of claim 39 further comprising:
a second dielectric layer, positioned on the top surface of the first stressed layer on the first transistor and the top surface of the first dielectric layer; and
at least a contact plug.

41. The structure of claim 39 wherein the first transistor further comprises:
a first gate dielectric layer;
a first gate, positioned on the first gate dielectric layer, the first gate having a sidewall;
a first spacer, positioned on the sidewall of the first gate; and
a source/drain region.

42. The structure of claim 39 wherein the second transistor further comprises:
a second gate dielectric layer;
a second gate, positioned on the second gate dielectric layer, the second gate having a sidewall;
a second spacer, positioned on the sidewall of the second gate; and
a source/drain region.

43. The structure of claim 39 wherein the first transistor comprises a PMOS transistor, and the second transistor comprises a NMOS transistor.

44. The structure of claim 43 wherein the first stressed layer is a compressive-stressed CESL, and the second stressed layer is a tensile-stressed CESL.

45. The structure of claim 39 wherein the first transistor comprises a NMOS transistor, and the second transistor comprises a PMOS transistor.

46. The structure of claim 45 wherein the first stressed layer is a tensile-stressed CESL, and the second stressed layer is a compressive-stressed CESL.

47. The structure of claim 39 further comprising a buffer layer on a portion of the isolation structure and the first transistor, and below the first stressed layer.

48. A structure of strained silicon channel CMOS transistor device comprising:
a substrate, the substrate having thereon at least a first active area, at least a second active area, and an isolation structure between the first active area and the second active area;
a first transistor, positioned on the first active area;
a second transistor, positioned on the second active area;
a first stressed layer, positioned on a portion of the isolation structure and the first transistor;
a second stressed layer, positioned on a portion of the first stressed layer above the first transistor, a portion of the isolation structure, and the second transistor; and
a first dielectric layer, positioned on a portion of the second stressed layer, wherein a top surface of the first stressed layer on the first transistor and a top surface of the first dielectric layer are in the same plane.

49. The structure of claim 48 further comprising:
a second dielectric layer, positioned on the first stressed layer; and
at least a contact plug.

50. The structure of claim 48 wherein the first transistor further comprises:
a first gate dielectric layer;
a first gate, positioned on the first gate dielectric layer, the first gate having a sidewall;
a first spacer, positioned on the sidewall of the first gate; and
a source/drain region.

51. The structure of claim 48wherein the second transistor further comprises:
a second gate dielectric layer;
a second gate, positioned on the second gate dielectric layer, the second gate having a sidewall;
a second spacer, positioned on the sidewall of the second gate; and
a source/drain region.

52. The structure of claim 48 wherein the first transistor comprises a PMOS transistor, and the second transistor comprises a NMOS transistor.

53. The structure of claim 52 wherein the first stressed layer is a compressive-stressed CESL, and the second stressed layer is a tensile-stressed CESL.

54. The structure of claim 48 wherein the first transistor comprises a NMOS transistor, and the second transistor comprises a PMOS transistor.

55. The structure of claim 54 wherein the first stressed layer is a tensile-stressed CESL, and the second stressed layer is a compressive-stressed CESL.

56. The structure of claim 48 further comprising a buffer layer on a portion of the isolation structure and the first transistor, and below the first stressed layer.
